(19) United States
(12) Patent Application Publication
(10) Pub. No.: US 2025/0029917 A1
(43) Pub. Date: Jan. 23, 2025

(54) METAL-INSULATOR-METAL CAPACITOR VIA STRUCTURES

(71) Applicant: International Business Machines Corporation, Armonk, NY (US)

(72) Inventors: Huimei Zhou, Albany, NY (US); Lili Cheng, Rexford, NY (US); Baozhen Li, South Burlington, VT (US); Chih-Chao Yang, Glenmont, NY (US); Miaomiao Wang, Albany, NY (US)

(21) Appl. No.: 18/356,386

(22) Filed: Jul. 21, 2023

(51) Int. Cl. H01L 23/522; H01L 23/528

(52) U.S. Cl. CPC H01L 23/5223; H01L 23/5226; H01L 23/5283; H01L 28/75

(57) ABSTRACT

A semiconductor device includes a metal-insulator-metal capacitor disposed between a first metallization level and a second metallization level, the metal-insulator-metal capacitor comprising a first electrode, a second electrode and a third electrode. A first via is extended from and contacts a conductive line of the second metallization level, and a second via is extended from and contacts the first via. The second via contacts the first electrode and the third electrode of the metal-insulator-metal capacitor. A slope of a side surface of the first via is different from a slope of a side surface of the second via.

### BACKGROUND

The field relates to semiconductors, and more specifically, to techniques for forming semiconductor structures including metal-insulator-metal (MIM) capacitors.

In semiconductor device manufacturing, capacitors are passive circuit components that are utilized in integrated circuitry of a semiconductor chip for various purposes. For example, capacitors can be utilized to decouple power supplies, to form memory elements, to form resistor-capacitor (RC) delay circuits, or provide various other circuit functions. While many types of capacitor structures can be utilized, MIM capacitors are commonly used for analog, microwave, and radio frequency (RF) applications. In general, planar MIM capacitors are comprised of two metallic plates separated by an insulator layer. As is known in the art, the capacitance of a MIM capacitor is (i) directly proportional to a surface area of the overlapping metallic plates, (ii) directly proportional to a dielectric constant of the dielectric material of the capacitor insulator layer, and (iii) inversely proportional to a thickness of the capacitor insulator layer.

### SUMMARY

Embodiments of the invention provide structures and techniques for forming vias for MIM capacitors.

In one embodiment, a semiconductor device includes a metal-insulator-metal capacitor disposed between a first metallization level and a second metallization level, the metal-insulator-metal capacitor comprising a first electrode, a second electrode and a third electrode. A first via is extended from and contacts a conductive line of the second metallization level, and a second via is extended from and contacts the first via. The second via contacts the first electrode and the third electrode of the metal-insulator-metal capacitor. A slope of a side surface of the first via is different from a slope of a side surface of the second via.

In another embodiment, a semiconductor device includes a metal-insulator-metal capacitor, and at least one interconnect structure disposed between a first metallization level and a second metallization level. The at least one interconnect structure comprises a first via and a second via extended from the first via. The second via contacts one or more electrodes of the metal-insulator-metal capacitor. Side surfaces of the first via are sloped differently from side surfaces of the second via.

In another embodiment, a semiconductor device includes a metal-insulator-metal capacitor. At least two vias are connected between a first pair of metal lines respectively corresponding to a first metallization level and a second metallization level. One of the at least two vias contacts a first electrode and a second electrode of the metal-insulator-metal capacitor, and the at least two vias have different shapes from each other. At least two other vias are connected between a second pair of metal lines respectively corresponding to the first metallization level and the second metallization level. The at least two other vias are isolated from the at least two vias, one of the at least two other vias contacts at least a third electrode of the metal-insulator-metal capacitor, and the at least two other vias have different shapes from each other.

These and other features and advantages of embodiments described herein will become more apparent from the accompanying drawings and the following detailed description.

### BRIEF DESCRIPTION OF THE DRAWINGS

FIG. 1 is a schematic cross-sectional view of a semiconductor structure at an intermediate stage of fabrication following deposition and patterning of a first conductive layer, according to an embodiment of the invention.

FIG. 2 is a schematic cross-sectional view of the semiconductor structure shown in FIG. 1 after deposition of a first high-k dielectric layer, according to an embodiment of the invention.

FIG. 3 is a schematic cross-sectional view of the semiconductor structure shown in FIG. 2 after deposition of a second conductive layer, according to an embodiment of the invention.

FIG. 4 is a schematic cross-sectional view of the semiconductor structure shown in FIG. 3 after patterning of the second conductive layer, according to an embodiment of the invention.

FIG. 5 is a schematic cross-sectional view of the semiconductor structure shown in FIG. 4 after deposition of a second high-k dielectric layer, according to an embodiment of the invention.

FIG. 6 is a schematic cross-sectional view of the semiconductor structure shown in FIG. 5 after deposition of a third conductive layer, according to an embodiment of the invention.

FIG. 7A is a schematic cross-sectional view of the semiconductor structure shown in FIG. 6 after patterning of the third conductive layer, according to an embodiment of the invention.

FIG. 7B is a schematic cross-sectional view of a semiconductor structure after patterning of the third conductive layer from FIG. 6, according to another embodiment of the invention.

FIG. 7C is a schematic cross-sectional view of a semiconductor structure after patterning of the third conductive layer from FIG. 6, according to another embodiment of the invention.

FIG. 8A is a schematic cross-sectional view of the semiconductor structure shown in FIG. 7A after deposition of an inter-layer dielectric (ILD) layer and a capping layer, according to an embodiment of the invention.

FIG. 8B is a schematic cross-sectional view of the semiconductor structure shown in FIG. 7B after deposition of an ILD layer and a capping layer, according to another embodiment of the invention.

FIG. 8C is a schematic cross-sectional view of the semiconductor structure shown in FIG. 7C after deposition of an ILD layer and a capping layer, according to another embodiment of the invention.

FIG. 9A is a schematic cross-sectional view of the semiconductor structure shown in FIG. 8A after removal of portions of the ILD layer to form trenches and via openings, according to an embodiment of the invention.

FIG. 9B is a schematic cross-sectional view of the semiconductor structure shown in FIG. 8B after removal of portions of the ILD layer to form trenches and via openings, according to another embodiment of the invention.

FIG. 9C is a schematic cross-sectional view of the semiconductor structure shown in FIG. 8C after removal of portions of the ILD layer to form trenches and via openings, according to another embodiment of the invention.

FIG. 10A is a schematic cross-sectional view of the semiconductor structure shown in FIG. 9A after removal of portions of the first and second dielectric layers to form via openings, according to an embodiment of the invention.

FIG. 10B is a schematic cross-sectional view of the semiconductor structure shown in FIG. 9B after removal of portions of the first and second dielectric layers to form via openings, according to another embodiment of the invention.

FIG. 10C is a schematic cross-sectional view of the semiconductor structure shown in FIG. 9C after removal of portions of the first and second dielectric layers to form via openings, according to another embodiment of the invention.

FIG. 11A is a schematic cross-sectional view of the semiconductor structure shown in FIG. 10A after removal of portions of another ILD layer to form via openings, according to an embodiment of the invention.

FIG. 11B is a schematic cross-sectional view of the semiconductor structure shown in FIG. 10B after removal of portions of another ILD layer to form via openings, according to another embodiment of the invention.

FIG. 11C is a schematic cross-sectional view of the semiconductor structure shown in FIG. 10C after removal of portions of another ILD layer to form via openings, according to another embodiment of the invention.

FIG. 12A is a schematic cross-sectional view of the semiconductor structure shown in FIG. 11A after filling in trenches and via openings with conductive material to form conductive lines and vias, according to an embodiment of the invention.

FIG. 12B is a schematic cross-sectional view of the semiconductor structure shown in FIG. 11B after filling in trenches and via openings with conductive material to form conductive lines and vias, according to another embodiment of the invention.

FIG. 12C is a schematic cross-sectional view of the semiconductor structure shown in FIG. 11C after filling in trenches and via openings with conductive material to form conductive lines and vias, according to another embodiment of the invention.

FIG. 13 is a schematic cross-sectional view of a semiconductor structure similar to the semiconductor structure shown in FIG. 12A including a fourth conductive layer for a metal-insulator-metal capacitor, according to an embodiment of the invention.

### DETAILED DESCRIPTION

Illustrative embodiments of the invention may be described herein in the context of illustrative structures and techniques for forming via structures for MIM capacitors where multiple vias between metallization levels have different shapes, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

In illustrative embodiments, decoupling MIM capacitors are formed within a back-end-of-line (BEOL) interconnect layer to provide capacitive decoupling between power supply lines such as, for example, positive power supply lines (e.g., VDD lines) and negative power supply lines (e.g., ground or VSS lines). As discussed in further detail below, MIM capacitor structures are fabricated using various types of via contact (or simply via) configurations within the BEOL interconnect structure to connect MIM capacitor electrodes (or capacitor plates) to metal lines which form wiring of a power distribution network for distributing power supply voltage of a first polarity (e.g., VDD) and power supply voltage of a second polarity (e.g., ground (GND) or VSS).

For example, such via configurations include multiple vias which provide vertical connections between metal lines of upper and lower metallization levels, wherein one or more of the vias are disposed through MIM capacitor electrodes to connect side surfaces of the capacitor electrodes to side surfaces of the vias. Multiple vias providing a connection between two metal lines of upper and lower metallization levels may have different shapes from each other and side surfaces with different slopes from each other. The different shapes can include, for example, trapezoidal, rectangular and/or square shapes. In illustrative embodiments, etching is limited to single metal layers (e.g., single electrodes) to avoid punching through multiple metal layers.

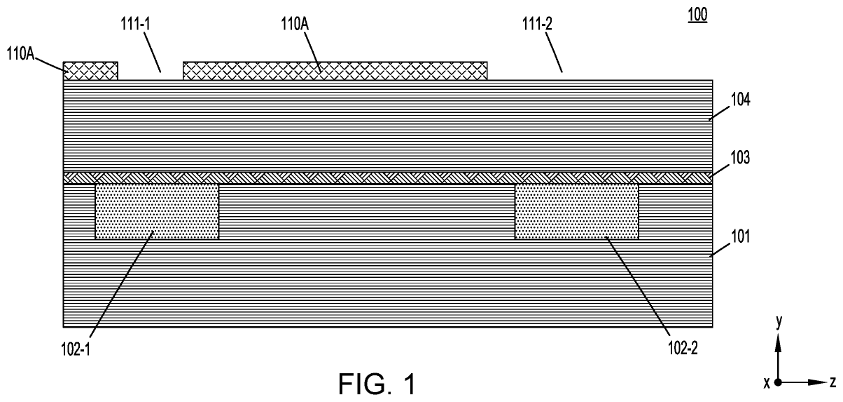

FIGS. 1-13 schematically illustrate techniques for fabricating a MIM capacitor structure including vias with different shapes formed between upper and lower metallization levels and contacting electrodes of a three-electrode or four-electrode MIM capacitor. To begin, FIG. 1 is a schematic cross-sectional view of a semiconductor structure 100 at an intermediate stage of fabrication following deposition and patterning of a first conductive layer 110A. The semiconductor structure 100 comprises a first ILD layer 101, conductive (e.g., metal) lines 102-1 and 102-2 (e.g., power distribution lines) formed in the first ILD layer 101, a first capping layer 103 formed on the first ILD layer 101, a second ILD layer 104 formed on the first capping layer 103, and the first conductive layer 110A formed on the second ILD layer 104. The first conductive layer 110A forms a first electrode (bottom electrode) of a MIM capacitor.

The first ILD layer 101 is formed of any suitable dielectric material that is commonly utilized in BEOL fabrication technologies. For example, the first ILD layer 101 can be formed of a dielectric material including, but not limited to, silicon oxide (SiO₂), silicon nitride (e.g., (Si₃N₄)), hydrogenated silicon carbon oxide (SiCOH), hydrogenated silicon carbide (SiCH), SiCNH, tetraethyl orthosilicate (TEOS), or other types of silicon-based low-k dielectrics (e.g., k less than about 4.0), porous dielectrics, or known ULK (ultra-low-k) dielectric materials (with k less than about 2.5). The first ILD layer 101 is deposited using known deposition techniques, such as, for example, ALD (atomic layer deposition), CVD (chemical vapor deposition) PECVD (plasma-enhanced CVD), or PVD (physical vapor deposition), or spin-on deposition.

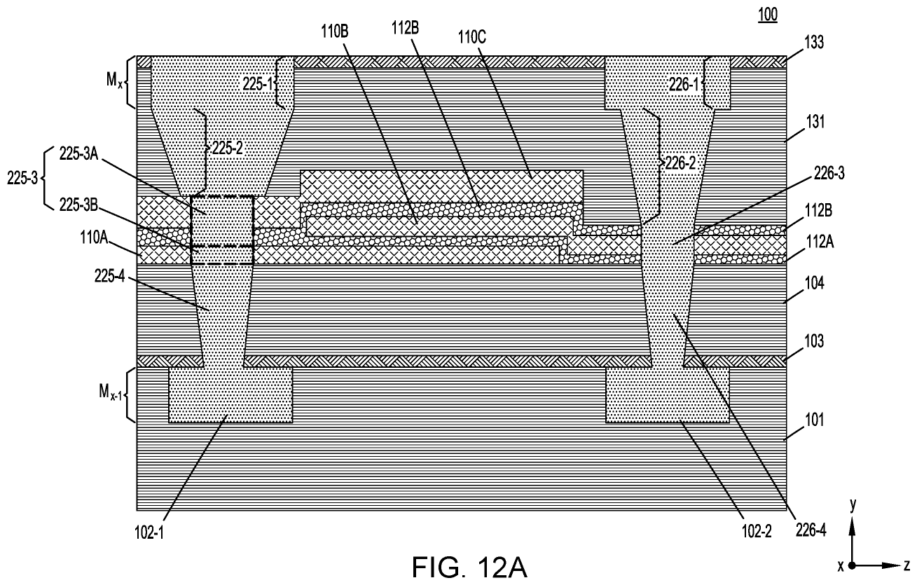

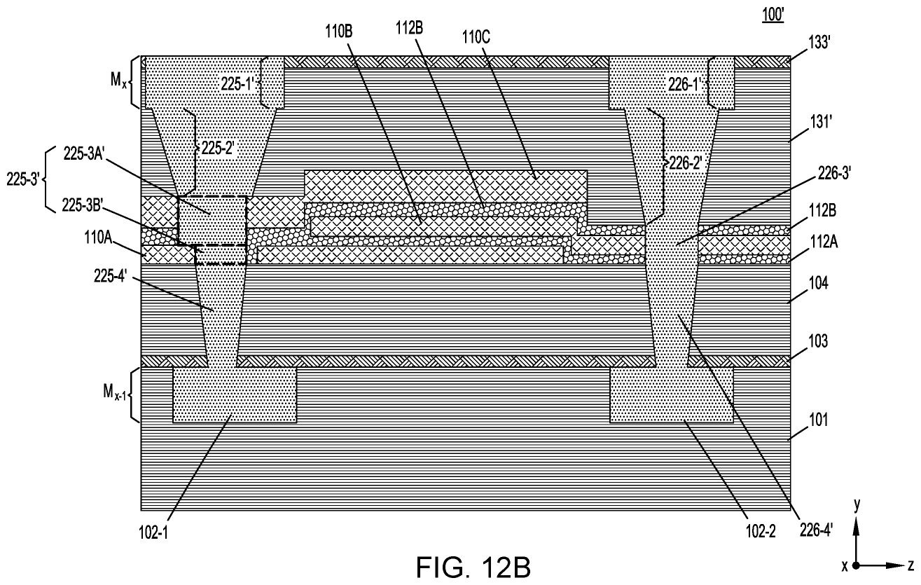

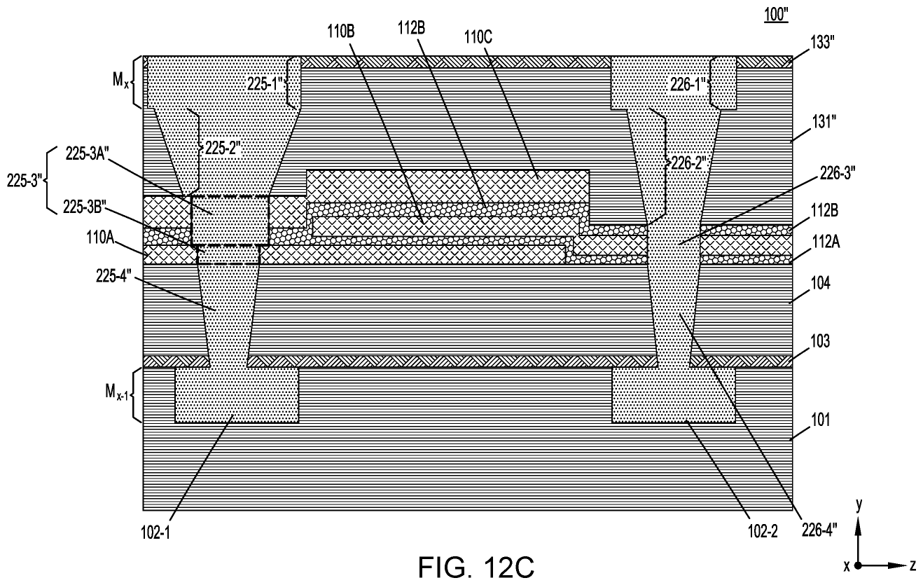

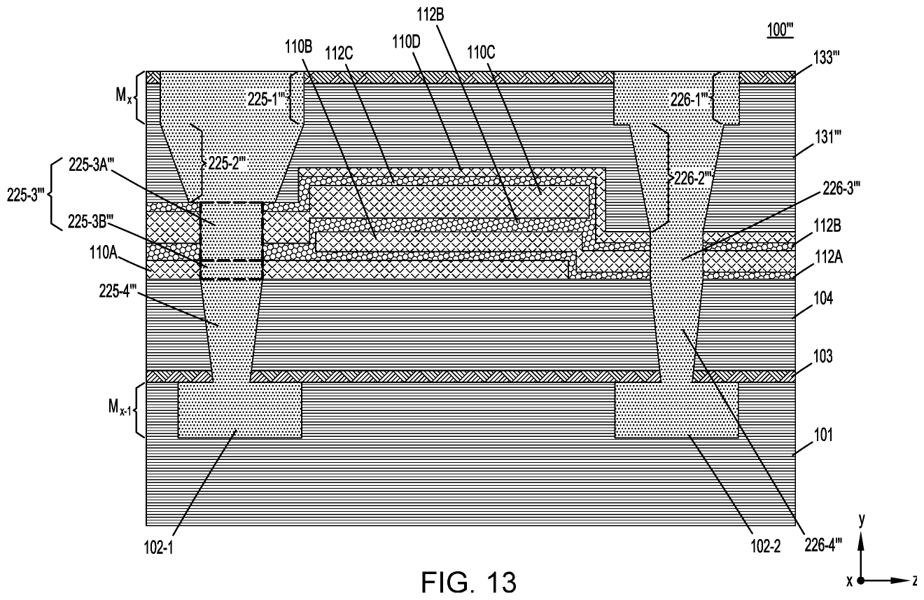

The conductive lines 102-1 and 102-2 comprise a plurality of parallel metal lines which, according to illustrative embodiments, include a positive power supply voltage line (e.g., VDD metal line), and a negative power supply voltage line (e.g., GND metal line). The conductive lines 102-1 and 102-2 are formed by a process which comprises patterning trenches in the first ILD layer 101, lining the trenches with a liner layer (e.g., diffusion barrier and/or seed layer), and filling the trenches with metallic material such as copper or other suitable metallic materials. In one embodiment, the conductive lines 102-1 and 102-2 are formed as part of a lower metallization level (e.g., M_{X-1} (see FIGS. 12A-12C and 13)).

The first capping layer 103 comprises a layer of insulating/dielectric material such as silicon nitride (SiN), silicon carbide (SiC), silicon carbon nitride (SiCN), hydrogenated silicon carbide (SiCH), a multilayer stack comprising the same or different types of dielectric materials, etc., or other suitable low-k dielectric materials which are non-reactive with the metallic material that is used to form conductive lines 102-1 and 102-2. In one example embodiment, the first capping layer 103 is formed with a thickness in a range of about 2 nm to about 60 nm, or thicker than 60 nm for the upper BEOL layers.

The second ILD layer 104 is formed of the same or similar material as the first ILD layer 101. The first conductive layer 110A, which forms a first electrode (bottom electrode) of a MIM capacitor, is formed by depositing a layer of metallic material on the second ILD layer 104 and patterning the layer of metallic material to form the first capacitor electrode. In one embodiment, the first conductive layer 110A is formed of titanium nitride (TiN). In other embodiments, the first conductive layer 110A is formed of other types of metallic materials such as aluminum nitride (AlN), which are suitable for the given application. The first conductive layer 110A is formed with a thickness in a range of about 10 nm to about 50 nm. As shown in FIG. 1, the first conductive layer 110A is patterned to form open regions 111-1 and 111-2 exposing portions of the second ILD layer 104. The patterning can be formed, for example, using an organic planarization layer (OPL) and lithography, and then wet etching or dry etching with, for example, chlorine (Cl⁻), etc. to form open regions 111-1 and 111-2.

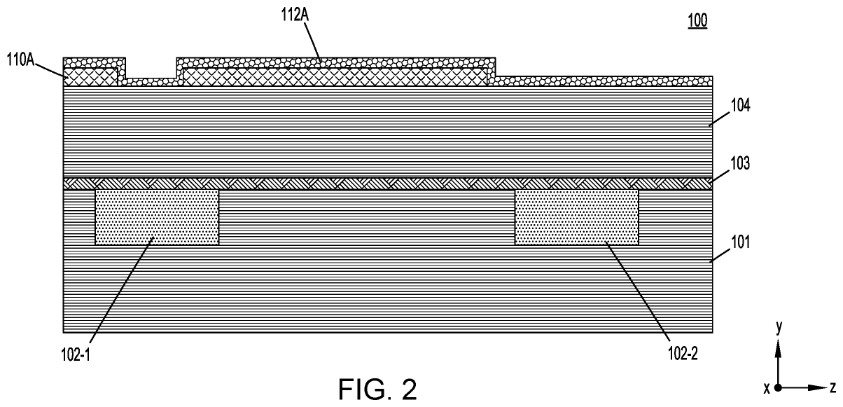

FIG. 2 is a schematic cross-sectional view of the semiconductor structure 100 shown in FIG. 1 after deposition of a first high-k dielectric layer 112A, according to an embodiment of the invention. Referring to FIG. 2, a first high-k dielectric layer 112A is deposited on a top surface and on exposed side surfaces of the first conductive layer 110A and on the second ILD layer 104 in the open regions 111-1 and 111-2. In one embodiment, the first high-k dielectric layer 112A is formed of a high-k dielectric material having a dielectric constant of about 3.9 or greater. For example, in some embodiments, the first high-k dielectric layer 112A is formed of a metal oxide such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, lead zinc niobate, or any suitable high-k dielectric material that is suitable for use as a dielectric layer for a MIM capacitor.

The thickness of the first high-k dielectric layer 112A will depend on the desired amount of capacitance of the MIM capacitor structure, wherein the capacitance is (i) directly proportional to the dielectric constant of the first high-k dielectric layer 112A and (ii) inversely proportional to the thickness of the first high-k dielectric layer 112A. The first high-k dielectric layer 112A is deposited using known methods such as ALD, for example, which allows for high conformality of the dielectric layer.

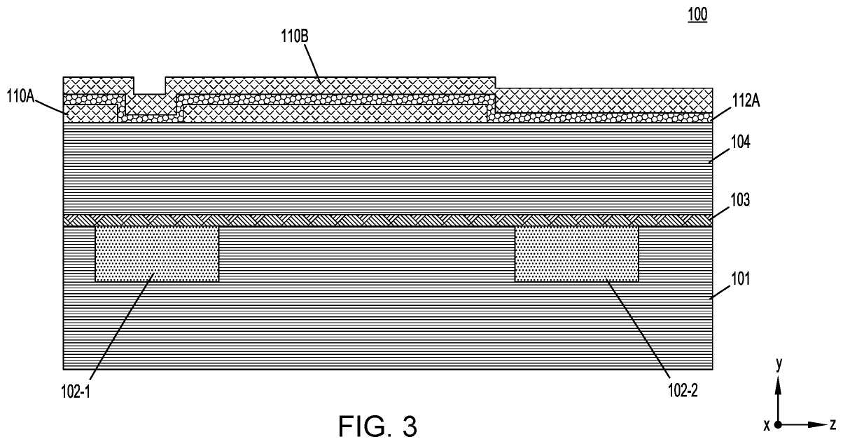

FIG. 3 is a schematic cross-sectional view of the semiconductor structure 100 shown in FIG. 2 after deposition of a second conductive layer 110B, according to an embodiment of the invention. The second conductive layer 110B forms a second electrode of a MIM capacitor. In one embodiment, the second conductive layer 110B is formed of the same metallic material as the first conductive layer 110A. For instance, the second conductive layer 110B is formed of TiN or AlN, or other metallic materials which are suitable for fabricating MIM capacitor electrodes. In another embodiment, the second conductive layer 110B can be formed of a metallic material which is different from the metallic material of the first conductive layer 110A. The second conductive layer 110B is formed with a thickness in a range of about 20 nm to about 50 nm. As can be seen the second conductive layer 110B is deposited on exposed top and side surfaces the first high-k dielectric layer 112A. Due to the conformal nature of the deposition of the second conductive layer 110B, the second conductive layer 110B includes areas of lower height (e.g., relative to a top surface of the second ILD layer 104) than other areas of the second conductive layer 110B. The areas of lower height of the second conductive layer 110B are consistent with the areas of lower height of the first high-k dielectric layer 112A.

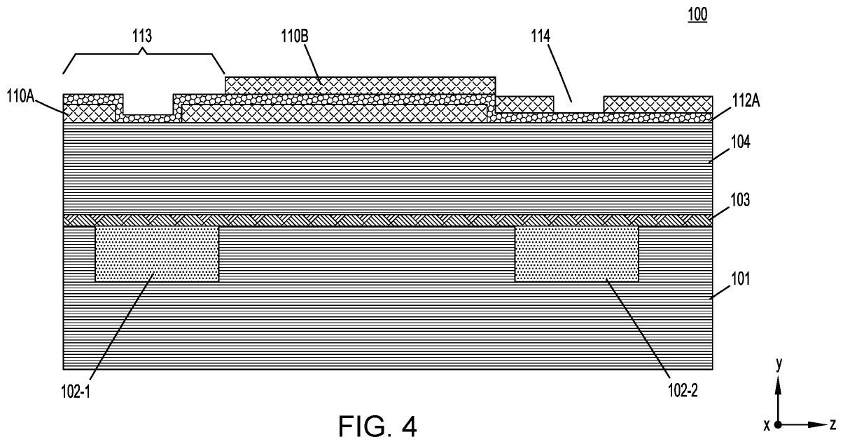

FIG. 4 is a schematic cross-sectional view of the semiconductor structure 100 shown in FIG. 3 after patterning of the second conductive layer 110B, according to an embodiment of the invention. The second conductive layer 110B is patterned to form open regions 113 and 114 exposing portions of the underlying first high-k dielectric layer 112A. The patterning can be performed using, for example, an OPL and lithography, and then wet etching or dry etching with, for example, chlorine (Cl⁻), etc. to form open regions 113 and 114.

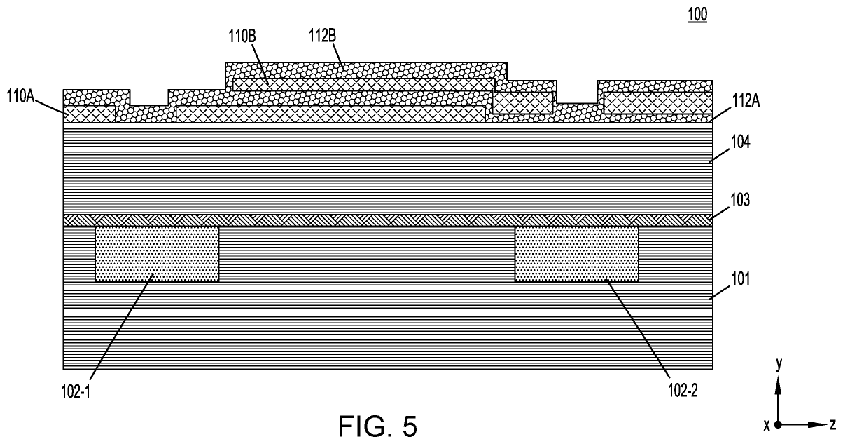

FIG. 5 is a schematic cross-sectional view of the semiconductor structure 100 shown in FIG. 4 after deposition of a second high-k dielectric layer 112B, according to an embodiment of the invention. Referring to FIG. 5, second high-k dielectric layer 112B is deposited on top surfaces and on exposed side surfaces of the second conductive layer 110B, as well as on exposed top surfaces and side surfaces of the first high-k dielectric layer 112A in the open regions 113 and 114. In one embodiment, the second high-k dielectric layer 112B is formed of the same or similar material and thickness as the first high-k dielectric layer 112A. Similar to the first high-k dielectric layer 112A, capacitance is (i) directly proportional to the dielectric constant of the second high-k dielectric layer 112B and (ii) inversely proportional to the thickness of the second high-k dielectric layer 112B.

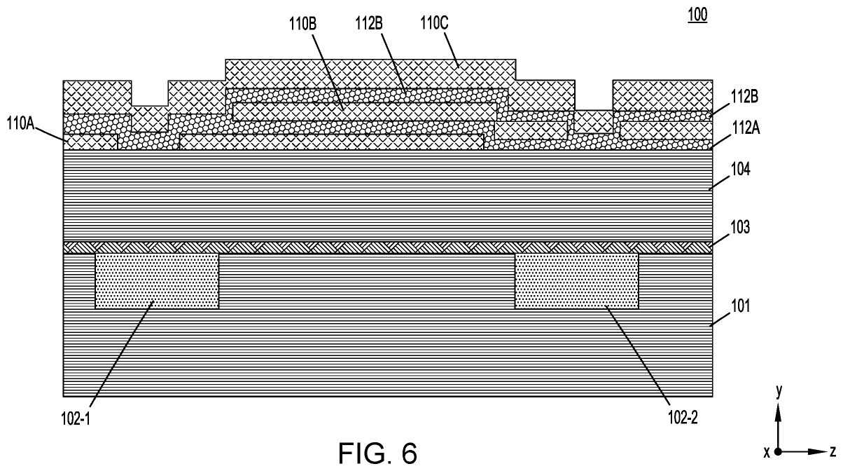

FIG. 6 is a schematic cross-sectional view of the semiconductor structure 100 shown in FIG. 5 after deposition of a third conductive layer 110C, according to an embodiment of the invention. The third conductive layer 110C forms a third electrode of a MIM capacitor (e.g., top electrode of a 3-electrode MIM capacitor). In one embodiment, the third conductive layer 110C is formed of the same metallic material as the first and second conductive layers 110A and 110B. For instance, the third conductive layer 110C is formed of TiN or AlN, or other metallic materials which are suitable for fabricating MIM capacitor electrodes. In another embodiment, the third conductive layer 110C can be formed of a metallic material which is different from the metallic materials of the first conductive layer 110A and/or the second conductive layer 110B. The third conductive layer 110C is formed with a thickness in a range of about 20 nm to about 50 nm. As can be seen the third conductive layer 110C is deposited on exposed top and side surfaces the second high-k dielectric layer 112B. Due to the conformal nature of the deposition of the third conductive layer 110C, the third conductive layer 110C includes areas of lower height (e.g., relative to a top surface of the second ILD layer 104) than other areas of the third conductive layer 110C. The areas of lower height of the third conductive layer 110C are consistent with the areas of lower height of the second high-k dielectric layer 112B.

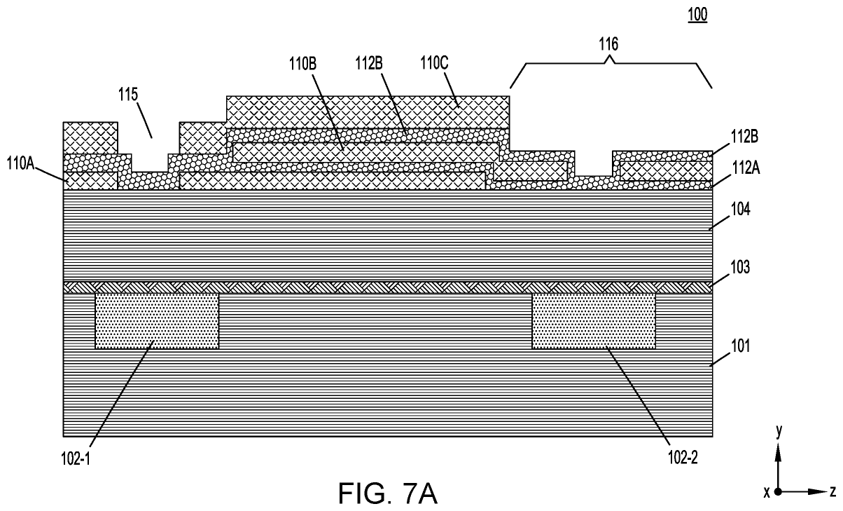

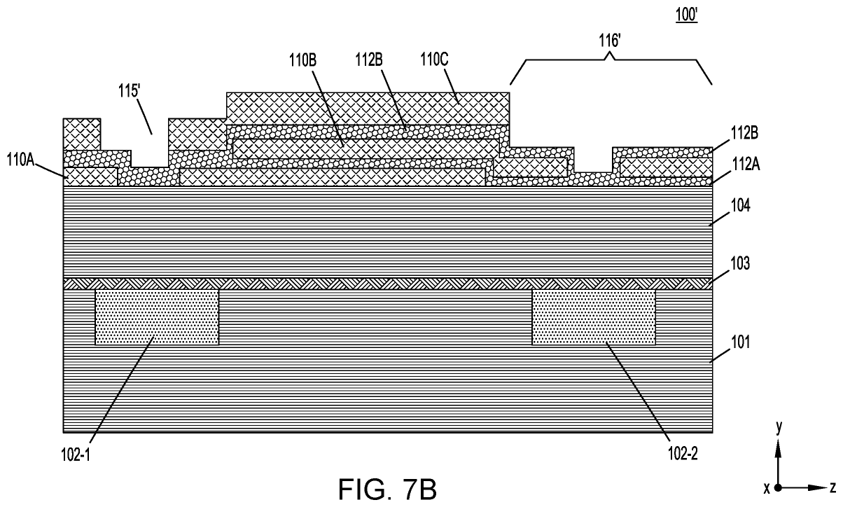

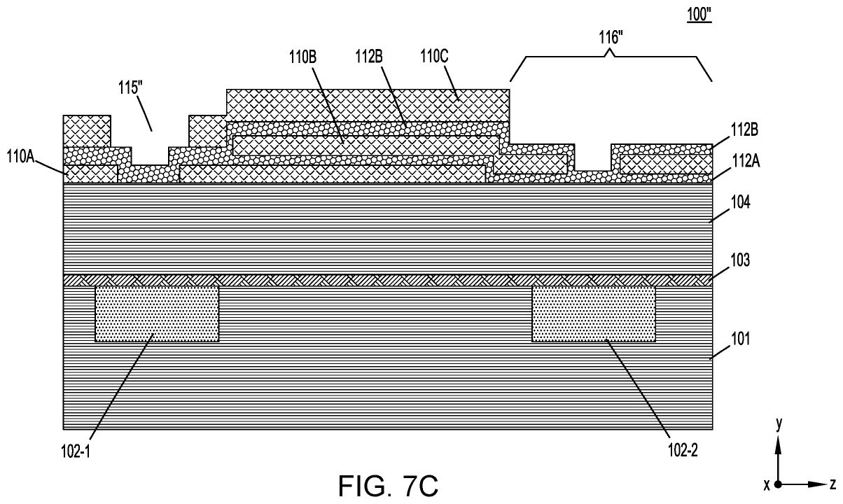

FIG. 7A is a schematic cross-sectional view of the semiconductor structure 100 shown in FIG. 6 after patterning of the third conductive layer 110C, according to an embodiment of the invention. The third conductive layer 110C is patterned to form open regions 115 and 116 exposing portions of the underlying second high-k dielectric layer 112B.

FIG. 7B is a schematic cross-sectional view of a semiconductor structure 100′ after patterning of the third conductive layer 110C from FIG. 6, according to another embodiment of the invention. In the semiconductor structure 100′, the third conductive layer 110C is patterned to form open regions 115′ and 116′ exposing portions of the underlying second high-k dielectric layer 112B. With respect to open region 115, open region 115′ in FIG. 7B is shifted leftward. The open region 116′ in FIG. 7B is the same as the open region 116 in FIG. 7A.

FIG. 7C is a schematic cross-sectional view of a semiconductor structure 100″ after patterning of the third conductive layer 110C from FIG. 6, according to another embodiment of the invention. The third conductive layer 110C is patterned to form open regions 115″ and 116″ exposing portions of the underlying second high-k dielectric layer 112B. With respect to open region 115, open region 115″ in FIG. 7C is wider, removing more of third conductive layer 110C in the patterning process. The open region 116″ in FIG. 7C is the same as the open region 116 and open region 116′ in FIGS. 7A and 7B. The patterning of the third conductive layer 110C in FIGS. 7A, 7B and 7C can be performed using, for example, an OPL and lithography, and then wet etching or dry etching with, for example, chlorine (Cl⁻), etc. to form open regions 115, 115′ and 115″ and open regions 116, 116′ and 116″.

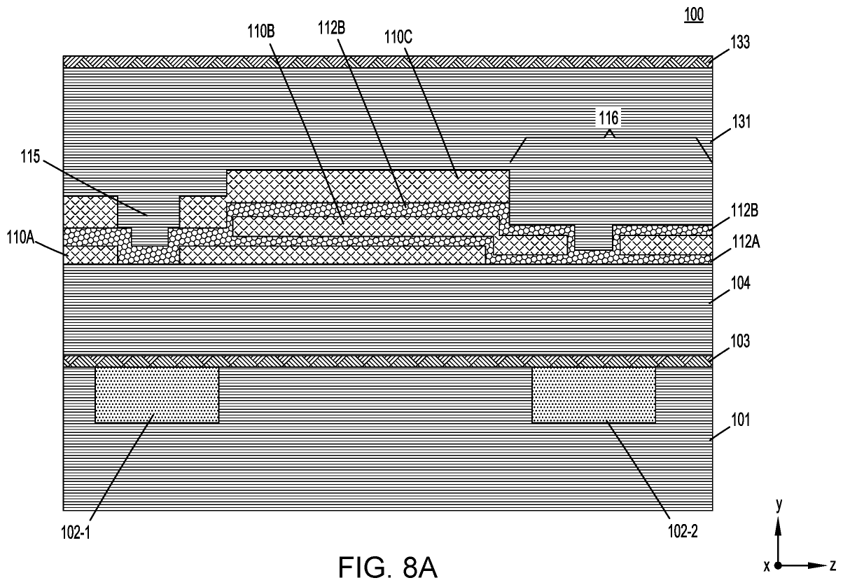

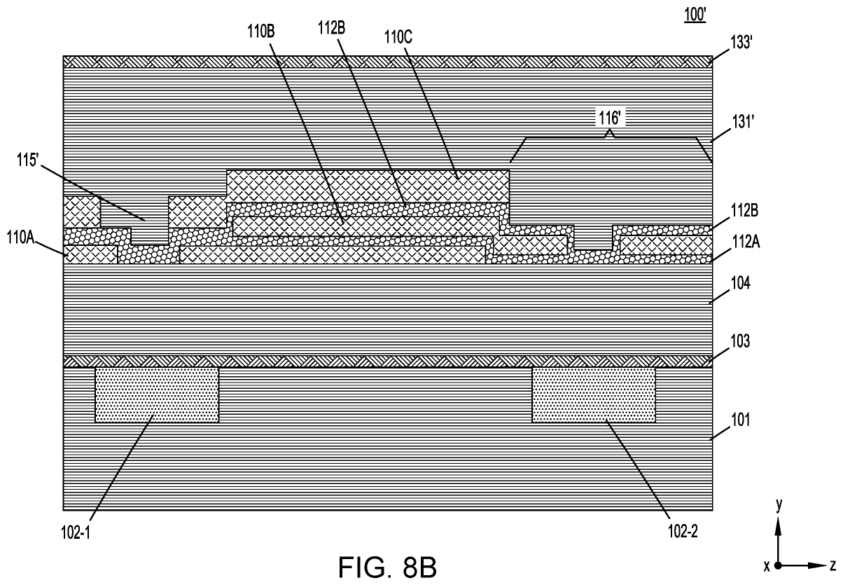

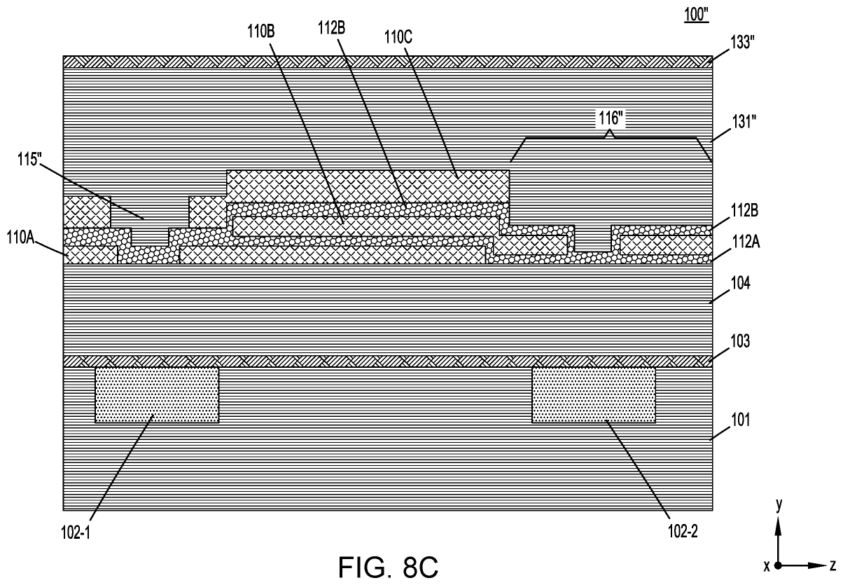

FIG. 8A is a schematic cross-sectional view of the semiconductor structure 100 shown in FIG. 7A after deposition of a third ILD layer 131 and a second capping layer 133, according to an embodiment of the invention. The third ILD layer 131 comprises the same material as or a similar material to that of the first and second ILD layers 101 and 104. The second capping layer comprises the same material as or a similar material to that of the first capping layer 103. The third ILD layer 131 is formed by a process which comprises depositing a layer of insulating material to cover the MIM capacitor comprising first, second and third conductive layers 110A, 110B and 110C, and first and second high-k dielectric layers 112A and 112B, and planarizing the deposited layer of insulating material using, e.g., a chemical mechanical polishing (CMP) process, to planarize the surface of the layer of insulating material down to a target thickness. The second capping layer 133 is deposited on the third ILD layer 131, and can also be planarized down to a target thickness.

Similar to FIG. 8A, FIG. 8B is a schematic cross-sectional view of the semiconductor structure 100′ shown in FIG. 7B after deposition of a third ILD layer 131′ and a second capping layer 133′, and FIG. 8C is a schematic cross-sectional view of the semiconductor structure 100″ shown in FIG. 7C after deposition of a third ILD layer 131″ and a second capping layer 133″. The third ILD layers 131′ and 131″ and the second capping layers 133′ and 133″ comprise the same materials as or similar materials to the third ILD layer 131 and the second capping layer 133, and are deposited by the same or similar processes as the third ILD layer 131 and the second capping layer 133.

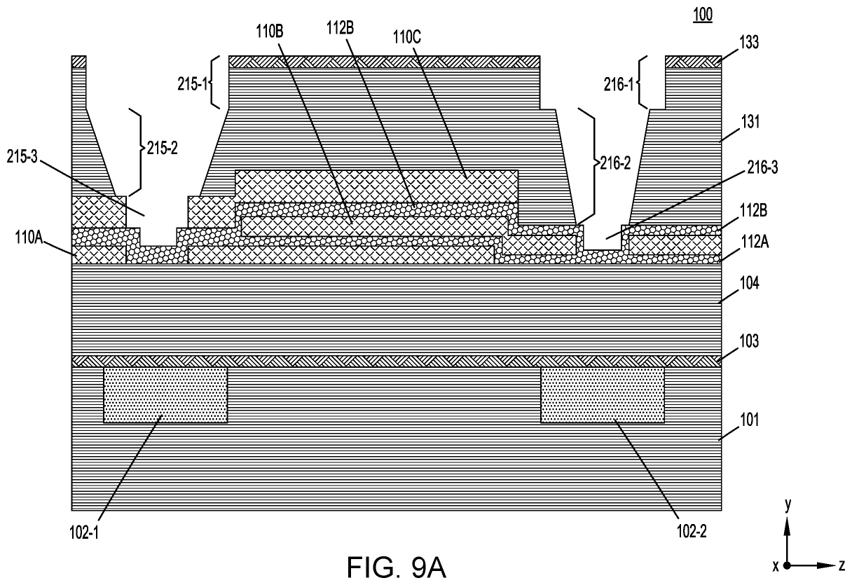

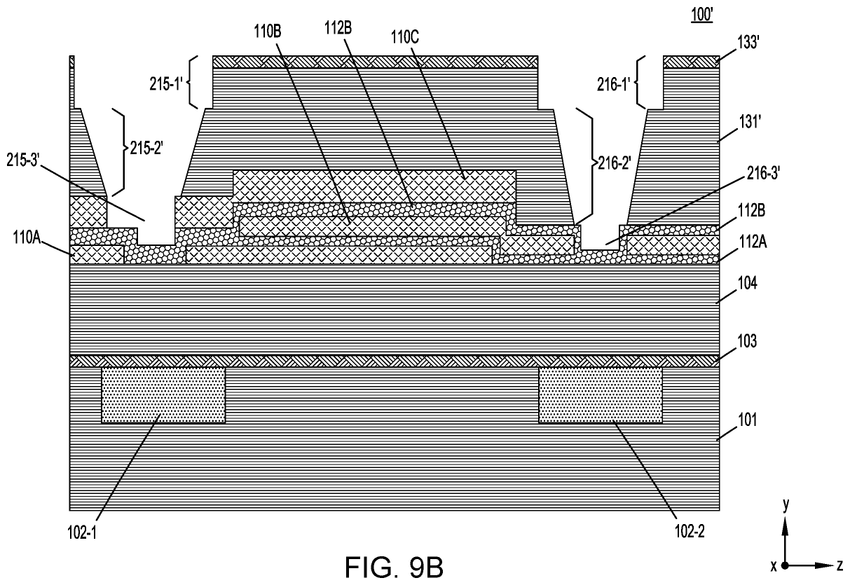

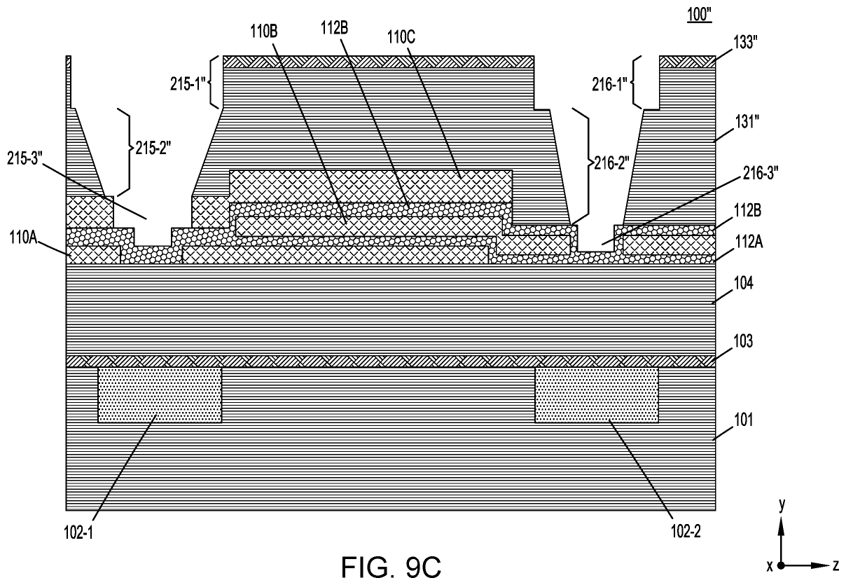

FIG. 9A is a schematic cross-sectional view of the semiconductor structure 100 shown in FIG. 8A after removal of portions of the third ILD layer 131 to form trenches 215-1 and 216-1 and via openings 215-2, 215-3, 216-2 and 216-3. The trenches 215-1 and 216-1 and via openings 215-2, 215-3, 216-2 and 216-3 are formed by any suitable process which comprises (i) forming an etch mask on the second capping layer 133 with openings exposing portions of the second capping layer 133 where the trenches 215-1 and 216-1 and via openings 215-2, 215-3, 216-2 and 216-3 are to be formed; and (ii) anisotropically etching exposed portions of the second capping layer 133 and underlying third ILD layer 131 to expose portions of the second high-k dielectric layer 112B. Referring back to FIG. 7A, the via opening 215-3 is the same as open region 115, and the via opening 216-3 comprises a portion of open region 116. As can be seen, via openings 215-2 and 216-2 have trapezoidal shapes.

FIG. 9B is a schematic cross-sectional view of the semiconductor structure 100′ shown in FIG. 8B after removal of portions of the third ILD layer 131′ to form trenches 215-1′ and 216-1′ and via openings 215-2′, 215-3′, 216-2′ and 216-3′. The trenches 215-1′ and 216-1′ and via openings 215-2′, 215-3′, 216-2′ and 216-3′ are formed by any suitable process which comprises (i) forming an etch mask on the second capping layer 133′ with openings exposing portions of the second capping layer 133′ where the trenches 215-1′ and 216-1′ and via openings 215-2′, 215-3′, 216-2′ and 216-3′ are to be formed; and (ii) anisotropically etching exposed portions of the second capping layer 133′ and underlying third ILD layer 131′ to expose portions of the second high-k dielectric layer 112B. Referring back to FIG. 7B, the via opening 215-3′ is the same as open region 115′, and the via opening 216-3′ comprises a portion of open region 116′. As can be seen, via openings 215-2′ and 216-2′ have trapezoidal shapes.

FIG. 9C is a schematic cross-sectional view of the semiconductor structure 100″ shown in FIG. 8C after removal of portions of portions of the third ILD layer 131″ to form trenches 215-1″ and 216-1″ and via openings 215-2″, 215-3″, 216-2″ and 216-3″. The trenches 215-1″ and 216-1″ and via openings 215-2″, 215-3″, 216-2″ and 216-3″ are formed by any suitable process which comprises (i) forming an etch mask on the second capping layer 133″ with openings exposing portions of the second capping layer 133″ where the trenches 215-1″ and 216-1″ and via openings 215-2″, 215-3″, 216-2″ and 216-3″ are to be formed; and (ii) anisotropically etching exposed portions of the second capping layer 133″ and underlying third ILD layer 131″ to expose portions of the second high-k dielectric layer 112B. Referring back to FIG. 7C, the via opening 215-3″ is the same as open region 115″, and the via opening 216-3″ comprises a portion of open region 116″. As can be seen, via openings 215-2″ and 216-2″ have trapezoidal shapes.

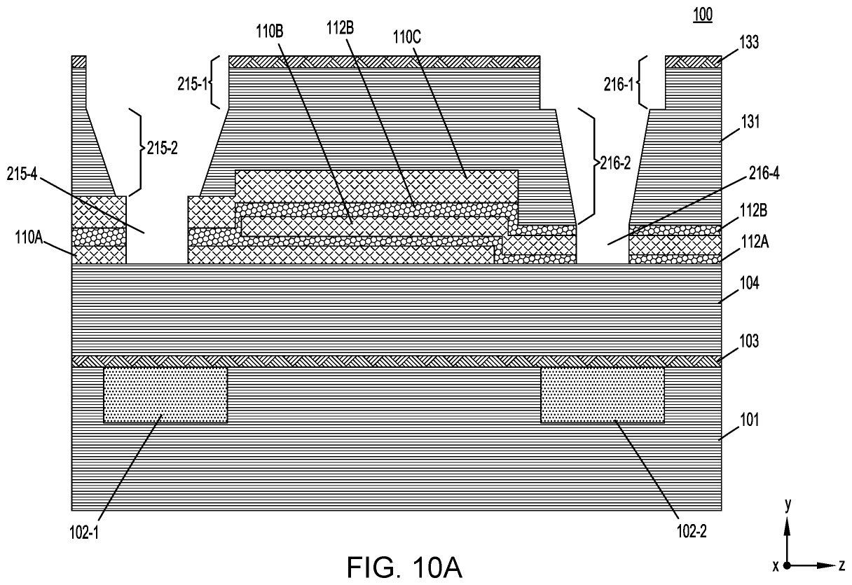

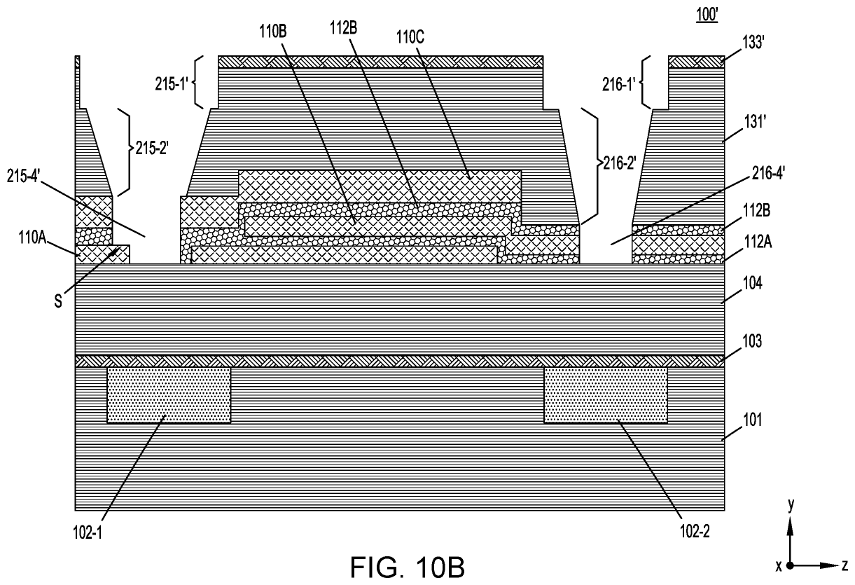

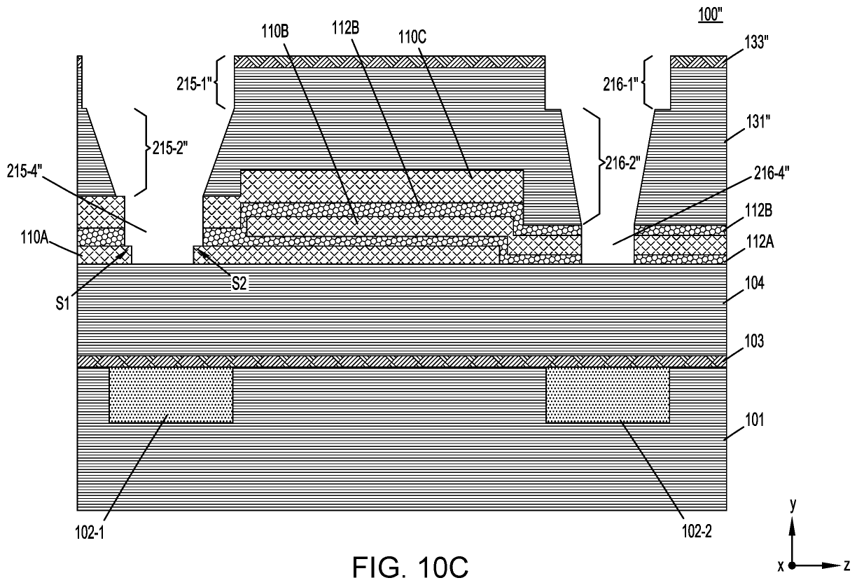

FIG. 10A is a schematic cross-sectional view of the semiconductor structure 100 shown in FIG. 9A after removal of portions of the first and second high-k dielectric layers 112A and 112B to form via openings 215-4 and 216-4, according to an embodiment of the invention. Following the processing in FIG. 9A, portions of the second high-k dielectric layer 112B are exposed in via openings 215-3 and 216-3. An anisotropic etching process is performed to remove the exposed portions of the second high-k dielectric layer 112B and then underlying portions of the first high-k dielectric layer 112A to form via openings 215-4 and 216-4, which expose parts of the second ILD layer 104. As can be seen, via openings 215-4 and 216-4 have square or rectangular shapes and the side surfaces of the via openings 215-4 and 216-4 are sloped differently (e.g., have different slopes) from the side surfaces of the via openings 215-2 and 216-2.

FIG. 10B is a schematic cross-sectional view of the semiconductor structure 100′ shown in FIG. 9B after removal of portions of the first and second high-k dielectric layers 112A and 112B to form via openings 215-4′ and 216-4′, according to another embodiment of the invention. Following the processing in FIG. 9B, portions of the second high-k dielectric layer 112B are exposed in via openings 215-3′ and 216-3′. An anisotropic etching process is performed to remove the exposed portions of the second high-k dielectric layer 112B and then underlying portions of the first high-k dielectric layer 112A to form via openings 215-4′ and 216-4′, which expose parts of the second ILD layer 104. As can be seen, via openings 215-4′ and 216-4′ have square or rectangular shapes and the side surfaces of the via openings 215-4′ and 216-4′ are sloped differently (e.g., have different slopes) from the side surfaces of the via openings 215-2′ and 216-2′. As can be seen in FIG. 10B, via opening 215-4′ includes a step portion S formed by part of the first conductive layer 110A protruding into the via opening 215-4′.

FIG. 10C is a schematic cross-sectional view of the semiconductor structure 100″ shown in FIG. 9C after removal of portions of the first and second high-k dielectric layers 112A and 112B to form via openings 215-4″ and 216-4″, according to another embodiment of the invention. Following the processing in FIG. 9C, portions of the second high-k dielectric layer 112B are exposed in via openings 215-3″ and 216-3″. An anisotropic etching process is performed to remove the exposed portions of the second high-k dielectric layer 112B and then underlying portions of the first high-k dielectric layer 112A to form via openings 215-4″ and 216-4″, which expose parts of the second ILD layer 104. As can be seen, via openings 215-4″ and 216-4″ have square or rectangular shapes and the side surfaces of the via openings 215-4″ and 216-4″ are sloped differently (e.g., have different slopes) from the side surfaces of the via openings 215-2″ and 216-2″. As can be seen in FIG. 10C, via opening 215-4″ includes step portions S1 and S2 formed by parts of the first conductive layer 110A protruding into the via opening 215-4″.

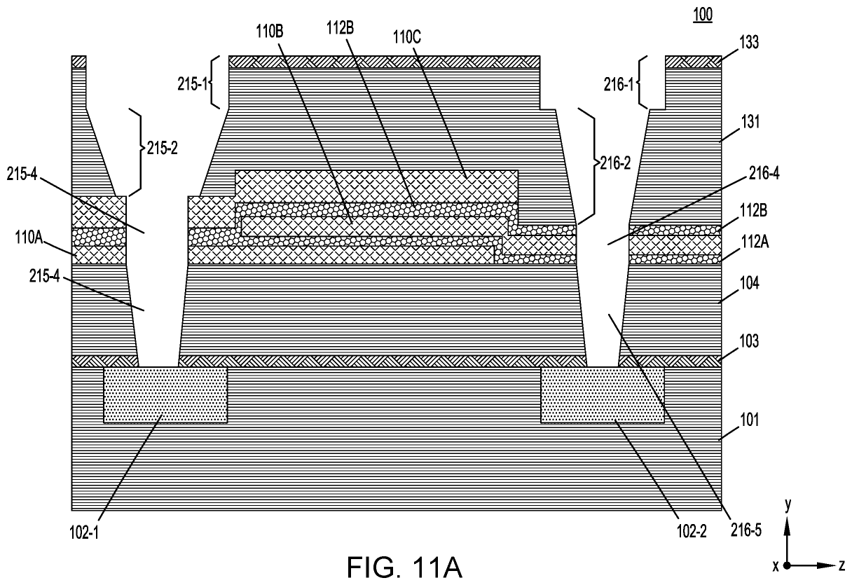

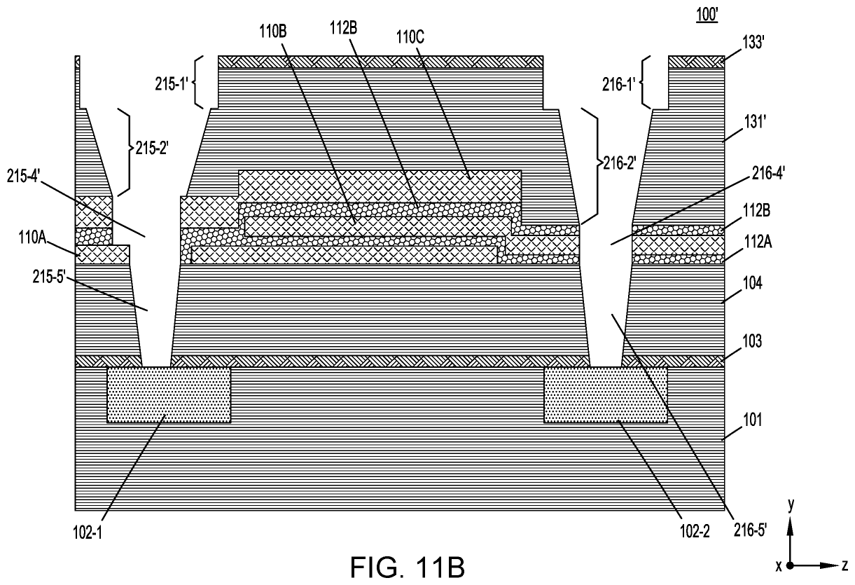

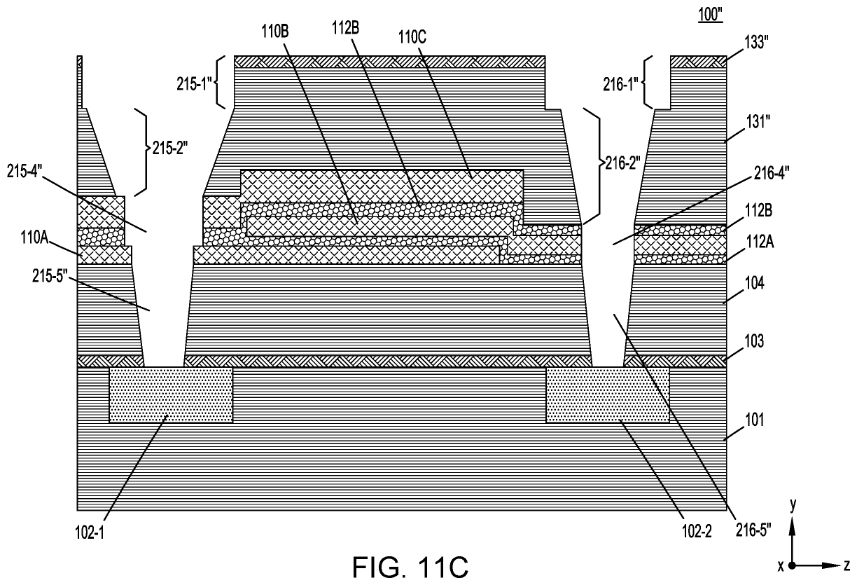

FIG. 11A is a schematic cross-sectional view of the semiconductor structure 100 shown in FIG. 10A after removal of portions of the second ILD layer 104 and underlying portions of the first capping layer 103 to form via openings 215-5 and 216-5, according to an embodiment of the invention. Following the processing in FIG. 10A, portions of the second ILD layer 104 are exposed in via openings 215-4 and 216-4. An anisotropic etching process is performed to remove the exposed portions of the second ILD layer 104 and then underlying portions of the first capping layer 103 to form via openings 215-5 and 216-5, which expose parts of the conductive lines 102-1 and 102-2. As can be seen, via openings 215-5 and 216-5 have trapezoidal shapes and the side surfaces of the via openings 215-5 and 216-5 are sloped differently (e.g., have different slopes) from the side surfaces of the via openings 215-4 and 216-4. In addition, the side surfaces of the via openings 215-5 and 216-5 can be sloped differently from the side surfaces of the via openings 215-2 and 216-2.

FIG. 11B is a schematic cross-sectional view of the semiconductor structure 100′ shown in FIG. 10B after removal of portions of the second ILD layer 104 and underlying portions of the first capping layer 103 to form via openings 215-5′ and 216-5′, according to an embodiment of the invention. Following the processing in FIG. 10B, portions of the second ILD layer 104 are exposed in via openings 215-4′ and 216-4′. An anisotropic etching process is performed to remove the exposed portions of the second ILD layer 104 and then underlying portions of the first capping layer 103 to form via openings 215-5′ and 216-5′, which expose parts of the conductive lines 102-1 and 102-2. As can be seen, via openings 215-5′ and 216-5′ have trapezoidal shapes and the side surfaces of the via openings 215-5′ and 216-5′ are sloped differently (e.g., have different slopes) from the side surfaces of the via openings 215-4′ and 216-4′. In addition, the side surfaces of the via openings 215-5′ and 216-5′ can be sloped differently from the side surfaces of the via openings 215-2′ and 216-2′.

FIG. 11C is a schematic cross-sectional view of the semiconductor structure 100″ shown in FIG. 10C after removal of portions of the second ILD layer 104 and underlying portions of the first capping layer 103 to form via openings 215-5″ and 216-5″, according to an embodiment of the invention. Following the processing in FIG. 10C, portions of the second ILD layer 104 are exposed in via openings 215-4″ and 216-4″. An anisotropic etching process is performed to remove the exposed portions of the second ILD layer 104 and then underlying portions of the first capping layer 103 to form via openings 215-5″ and 216-5″, which expose parts of the conductive lines 102-1 and 102-2. As can be seen, via openings 215-5″ and 216-5″ have trapezoidal shapes and the side surfaces of the via openings 215-5″ and 216-5″ are sloped differently (e.g., have different slopes) from the side surfaces of the via openings 215-4″ and 216-4″. In addition, the side surfaces of the via openings 215-5″ and 216-5″ can be sloped differently from the side surfaces of the via openings 215-2″ and 216-2″.

FIG. 12A is a schematic cross-sectional view of the semiconductor structure 100 shown in FIG. 11A after filling in trenches 215-1 and 216-1 and via openings 215-2, 215-4, 215-5, 216-2, 216-4 and 216-5 with conductive material to form conductive lines 225-1 and 226-1 and vias 225-2, 225-3, 225-4, 226-2, 226-3 and 226-4, according to an embodiment of the invention. In an illustrative embodiment, one or more layers of liner material are deposited to line the side and bottom surfaces of the trenches 215-1 and 216-1 and via openings 215-2, 215-4, 215-5, 216-2, 216-4 and 216-5 with a liner (e.g., diffusion barrier layer and/or seed layer), and a layer of metallic material to is deposited to fill the trenches 215-1 and 216-1 and via openings 215-2, 215-4, 215-5, 216-2, 216-4 and 216-5. The surface of the semiconductor structure 100 is planarized down to the upper surface of the second capping layer 133 to remove excess liner and metallic material of the deposited layers, resulting in the structure shown in FIG. 12A. In one or more embodiments, the liner may be formed of one or more conformal layers of metallic material such as a titanium (Ti) and/or titanium nitride (TiN) liner, to line the bottom and side surfaces of the trenches 215-1 and 216-1 and via openings 215-2, 215-4, 215-5, 216-2, 216-4 and 216-5. In one or more embodiments, the metallic fill material comprises, for example, copper, tungsten, cobalt, ruthenium, etc.

As can be seen, vias 225-2 and 226-2 have trapezoidal shapes, via 225-3 includes portions 225-3A and 225-3B with square or rectangular shapes, via 226-3 has a square or rectangular shape, and vias 225-4 and 226-4 have trapezoidal shapes. The side surfaces of the vias 225-3 and 226-3 are sloped differently (e.g., have different slopes) from the side surfaces of the vias 225-2 and 226-2, and from the side surfaces of the vias 225-4 and 226-4. In addition, the side surfaces of the vias 225-2 and 226-2 can have different slopes from the side surfaces of the vias 225-4 and 226-4. Further, the side surfaces of the portions 225-3A and 225-3B may be sloped differently or the same as each other.

The conductive lines 225-1 and 226-2 are part of a metallization layer Mₓ and the vias 225-2 and 226-2 extend from and contact the conductive lines 225-1 and 226-2. The vias 225-3 and 226-3 extend from and contact the vias 225-2 and 226-2, respectively. The via 225-3 contacts a first electrode (e.g., first conductive layer 110A) and a third electrode (e.g., third conductive layer 110C) of a MIM capacitor, and the via 226-3 contacts a second electrode (e.g., second conductive layer 110B) of the MIM capacitor. Portions of the first and second high-k dielectric layers 112A and 112B are disposed between the first and third electrodes, and isolate the first and third electrodes from the second electrode.

The via 225-3 contacts the first electrode and the third electrode at the side surfaces of the via 225-3, and side surfaces of the first electrode and the third electrode. The via 226-3 contacts the second electrode at the side surface of the via 226-3, and side surfaces of the second electrode. The vias 225-4 and 226-4 respectively extend from the vias 225-3 and 226-3 to contact the conductive lines 102-1 and 102-2, which are part of the metallization layer Mₓ₋₁.

FIG. 12B is a schematic cross-sectional view of the semiconductor structure 100′ shown in FIG. 11B after filling in trenches 215-1′ and 216-1′ and via openings 215-2′, 215-4′, 215-5′, 216-2′, 216-4′ and 216-5′ with conductive material to form conductive lines 225-1′ and 226-1′ and vias 225-2′, 225-3′, 225-4′, 226-2′, 226-3′ and 226-4′, according to an embodiment of the invention. In an illustrative embodiment, one or more layers of liner material are deposited to line the side and bottom surfaces of the trenches 215-1′ and 216-1′ and via openings 215-2′, 215-4′, 215-5′, 216-2′, 216-4′ and 216-5′ with a liner (e.g., diffusion barrier layer and/or seed layer), and a layer of metallic material to is deposited to fill the trenches 215-1′ and 216-1′ and via openings 215-2′, 215-4′, 215-5′, 216-2′, 216-4′ and 216-5′. The surface of the semiconductor structure 100′ is planarized down to the upper surface of the second capping layer 133′ to remove excess liner and metallic material of the deposited layers, resulting in the structure shown in FIG. 12B. In one or more embodiments, the liner may be formed of one or more conformal layers of metallic material such as a Ti and/or TiN liner, to line the bottom and side surfaces of the trenches 215-1′ and 216-1′ and via openings 215-2′, 215-4′, 215-5′, 216-2′, 216-4′ and 216-5′. In one or more embodiments, the metallic fill material comprises, for example, copper, tungsten, cobalt, ruthenium, etc.

As can be seen, vias 225-2′ and 226-2′ have trapezoidal shapes, via 225-3′ includes portions 225-3A′ and 225-3B′ with square or rectangular shapes, via 226-3′ has a square or rectangular shape, and vias 225-4′ and 226-4′ have trapezoidal shapes. The side surfaces of the vias 225-3′ and 226-3′ are sloped differently (e.g., have different slopes) from the side surfaces of the vias 225-2′ and 226-2′, and from the side surfaces of the vias 225-4′ and 226-4′. In addition, the side surfaces of the vias 225-2′ and 226-2′ can have different slopes from the side surfaces of the vias 225-4′ and 226-4′. Further, the side surfaces of the portions 225-3A′ and 225-3B′ may be sloped differently or the same as each other.

The conductive lines 225-1′ and 226-2′ are part of a metallization layer Mₓ and the vias 225-2′ and 226-2′ extend from and contact the conductive lines 225-1′ and 226-2′. The vias 225-3′ and 226-3′ extend from and contact the vias 225-2′ and 226-2′, respectively. The via 225-3′ contacts a first electrode (e.g., first conductive layer 110A) and a third electrode (e.g., third conductive layer 110C) of a MIM capacitor, and the via 226-3′ contacts a second electrode (e.g., second conductive layer 110B) of the MIM capacitor. The via 225-3′ includes a first portion 225-3A′ on top of a second portion 225-3B′ and contacting the first and the third electrode, where the second portion 225-3B′ contacts the first electrode and is narrower (e.g., has a lower critical dimension between side surfaces) than the first portion due to the step portion S of the first conductive layer 110A. Portions of the first and second high-k dielectric layers 112A and 112B are disposed between the first and third electrodes, and isolate the first and third electrodes from the second electrode.

The first portion 225-3A′ of the via 225-3′ contacts the third electrode at side surfaces of the first portion 225-3A′ of the via 225-3′ and the first electrode at a bottom surface of the first portion 225-3A′ of the via 225-3′. The first portion 225-3A′ of the via 225-3′ contacts the third electrode at side surfaces of the third electrode and contacts a top surface of the first electrode. The second portion 225-3B′ of the via 225-3′ contacts the first electrode at a side surface of the second portion 225-3B′ of the via 225-3′ and a side surface of the first electrode. The via 226-3′ contacts the second electrode at the side surfaces of the via 226-3′, and side surfaces of the second electrode. The vias 225-4′ and 226-4′ respectively extend from the vias 225-3′ and 226-3′ to contact the conductive lines 102-1 and 102-2, which are part of the metallization layer Mₓ₋₁.

FIG. 12C is a schematic cross-sectional view of the semiconductor structure 100″ shown in FIG. 11C after filling in trenches 215-1″ and 216-1″ and via openings 215-2″, 215-4″, 215-5″, 216-2″, 216-4″ and 216-5″ with conductive material to form conductive lines 225-1″ and 226-1″ and vias 225-2″, 225-3″, 225-4″, 226-2″, 226-3″ and 226-4″, according to an embodiment of the invention. In an illustrative embodiment, one or more layers of liner material are deposited to line the side and bottom surfaces of the trenches 215-1″ and 216-1″ and via openings 215-2″, 215-4″, 215-5″, 216-2″, 216-4″ and 216-5″ with a liner (e.g., diffusion barrier layer and/or seed layer), and a layer of metallic material to is deposited to fill the 215-1″ and 216-1″ and via openings 215-2″, 215-4″, 215-5″, 216-2″, 216-4″ and 216-5″. The surface of the semiconductor structure 100″ is planarized down to the upper surface of the second capping layer 133″ to remove excess liner and metallic material of the deposited layers, resulting in the structure shown in FIG. 12C. In one or more embodiments, the liner may be formed of one or more conformal layers of metallic material such as a Ti and/or TiN liner, to line the bottom and side surfaces of the trenches 215-1″ and 216-1″ and via openings 215-2″, 215-4″, 215-5″, 216-2″, 216-4″ and 216-5″. In one or more embodiments, the metallic fill material comprises, for example, copper, tungsten, cobalt, ruthenium, etc.

As can be seen, vias 225-2″ and 226-2″ have trapezoidal shapes, via 225-3″ includes portions 225-3A″ and 225-3B″ with square or rectangular shapes, via 226-3″ has a square or rectangular shape, and vias 225-4″ and 226-4″ have trapezoidal shapes. The side surfaces of the vias 225-3″ and 226-3″ are sloped differently (e.g., have different slopes) from the side surfaces of the vias 225-2″ and 226-2″, and from the side surfaces of the vias 225-4″ and 226-4″. In addition, the side surfaces of the vias 225-2″ and 226-2″ can have different slopes from the side surfaces of the vias 225-4″ and 226-4″. Further, the side surfaces of the portions 225-3A″ and 225-3B″ may be sloped differently or the same as each other.

The conductive lines 225-1″ and 226-2″ are part of a metallization layer Mₓ and the vias 225-2″ and 226-2″ extend from and contact the conductive lines 225-1″ and 226-2″. The vias 225-3″ and 226-3″ extend from and contact the vias 225-2″ and 226-2″, respectively. The via 225-3″ contacts a first electrode (e.g., first conductive layer 110A) and a third electrode (e.g., third conductive layer 110C) of a MIM capacitor, and the via 226-3″ contacts a second electrode (e.g., second conductive layer 110B) of the MIM capacitor. The via 225-3″ includes a first portion 225-3A″ on top of a second portion 225-3B″ and contacting the first and the third electrode, where the second portion 225-3B″ contacts the first electrode and is narrower (e.g., has a lower critical dimension between side surfaces) than the first portion 225-3A″ due to the step portions S1 and S2 of the first conductive layer 110A. Portions of the first and second high-k dielectric layers 112A and 112B are disposed between the first and third electrodes, and isolate the first and third electrodes from the second electrode.

The first portion 225-3A″ of the via 225-3″ contacts the third electrode at side surfaces of the first portion 225-3A″ of the via 225-3″ and the first electrode at a bottom surface of the first portion 225-3A″ of the via 225-3″. The first portion 225-3A″ of the via 225-3″ contacts the third electrode at side surfaces of the third electrode and contacts top surfaces of the first electrode. The second portion 225-3B″ of the via 225-3″ contacts the first electrode at side surfaces of the second portion 225-3B″ of the via 225-3″ and side surfaces of the first electrode. The via 226-3″ contacts the second electrode at the side surfaces of the via 226-3″, and side surfaces of the second electrode. The vias 225-4″ and 226-4″ respectively extend from the vias 225-3″ and 226-3″ to contact the conductive lines 102-1 and 102-2, which are part of the metallization layer Mₓ₋₁.

FIG. 13 is a schematic cross-sectional view of a semiconductor structure 100′″ similar to the semiconductor structure 100 shown in FIG. 12A. Unlike the semiconductor structure 100, the semiconductor structure 100′″ includes a third high-k dielectric layer 112C on the third conductive layer 110C and a fourth conductive layer 110D on the third high-k dielectric layer 112C to form a MIM capacitor having four electrodes, where the fourth conductive layer 110D is a fourth electrode. In the semiconductor structure 100′″, vias 225-2′″ and 226-2′″ have trapezoidal shapes, via 225-3′″, includes portions 225-3A′″ and 225-3B′″ with square or rectangular shapes, via 226-3′″ has a square or rectangular shape, and vias 225-4′″ and 226-4′″ have trapezoidal shapes. The side surfaces of the vias 225-3′″ and 226-3′″ are sloped differently (e.g., have different slopes) from the side surfaces of the vias 225-2′″ and 226-2′″, and from the side surfaces of the vias 225-4′″ and 226-4′″. In addition, the side surfaces of the vias 225-2′″ and 226-2′″ can have different slopes from the side surfaces of the vias 225-4′″ and 226-4′″. Further, the side surfaces of the portions 225-3A′″ and 225-3B′″ may be sloped differently or the same as each other.

The conductive lines 225-1′″ and 226-2′″ are part of a metallization layer M_{X} and the vias 225-2′″ and 226-2′″ extend from and contact the conductive lines 225-1′″ and 226-2′″. The vias 225-3′″ and 226-3′″ extend from and contact the vias 225-2′″ and 226-2′″, respectively. The via 225-3′″ contacts a first electrode (e.g., first conductive layer 110A) and a third electrode (e.g., third conductive layer 110C) of a MIM capacitor, and the via 226-3′″ contacts a fourth electrode (e.g., fourth conductive layer 110D) and a second electrode (e.g., second conductive layer 110B) of the MIM capacitor. Portions of the first and second high-k dielectric layers 112A and 112B are disposed between the first and third electrodes, and portions of the first, second and third high-k dielectric layers 112A, 112B and 112C isolate the first and third electrodes from the second and fourth electrodes. Portions of the second and third high-k dielectric layers 112B and 112C are disposed between the second and fourth electrodes, and portions of the first, second and third high-k dielectric layers 112A, 112B and 112C isolate the second and fourth electrodes from the first and third electrodes.

The via 225-3′″ contacts the first electrode and the third electrode at the side surfaces of the via 225-3′″, and side surfaces of the first electrode and the third electrode. The via 226-3′″ contacts the second and fourth electrodes at the side surface of the via 226-3′″, and side surfaces of the second and fourth electrode. The vias 225-4′″ and 226-4′″ respectively extend from the vias 225-3′″ and 226-3′″ to contact the conductive lines 102-1 and 102-2, which are part of the metallization layer Mₓ₋₁.

The semiconductor structures 100, 100′, 100″ and 100′″ comprise at least an upper metallization level Mₓ and a lower metallization level Mₓ₋₁. In illustrative embodiments, the conductive lines 225-1 and 226-2, 225-1′ and 226-1′, 225-1″ and 226-1″ and 225-1′″ and 226-1″ of the upper metallization level Mₓ are parallel power distribution lines and the conductive lines 102-1 and 102-2 of the lower metallization level Mₓ₋₁ are parallel power distribution lines. For example, both conductive line 225-1/225-1′/225-1″/225-1′″ and conductive line 102-1 may be negative power supply voltage lines (e.g., GND of VSS lines) or may be positive power supply voltage lines (e.g., VDD lines). Similarly, both conductive line 226-1/226-1′/226-1″/226-1′″ and second conductive line 102-2 may be negative power supply voltage lines (e.g., GND of VSS lines) or may be positive power supply voltage lines (e.g., VDD lines). For example, the combination of conductive line 225-1/225-1′/225-1″/225-1′″ and conductive line 102-1 can function as an anode, and the combination of conductive line 226-1/226-1′/226-1″/226-1′″ and conductive line 102-2 can function as a cathode.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. An example integrated circuit includes one or more semiconductor devices with the above-described contact configurations and transistors stacked in a staggered configuration.

As noted above, illustrative embodiments correspond to structures and techniques for forming via structures for MIM capacitors where multiple vias between metallization levels have different shapes, along with illustrative apparatus, systems and devices formed using such methods. Multiple vias which provide vertical connections between metal lines of upper and lower metallization levels are disposed through MIM capacitor electrodes to connect side surfaces of the capacitor electrodes to side surfaces of the vias. The vias which provide a connection between two metal lines of upper and lower metallization levels may have different shapes from each other and side surfaces with different slopes from each other. The different shapes can include, for example, trapezoidal, rectangular and/or square shapes. In illustrative embodiments, etching is limited to single metal layers (e.g., single electrodes) to avoid punching through multiple metal layers.

It should be understood that the various layers, structures, and regions shown in the figures are schematic illustrations that are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount. To provide spatial context, XYZ Cartesian coordinates are shown in the drawings of semiconductor device structures. It is to be understood that the term “vertical” as used herein denotes a Z-direction of the Cartesian coordinates shown in the drawings, and that the terms “horizontal” or “lateral” as used herein denote an X-direction and/or a Y-direction of the Cartesian coordinates shown in the drawings, which is perpendicular to the Z-direction.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a metal-insulator-metal capacitor disposed between a first metallization level and a second metallization level, the metal-insulator-metal capacitor comprising a first electrode, a second electrode and a third electrode;
a first via extended from and contacting a conductive line of the second metallization level; and
a second via extended from and contacting the first via;
wherein the second via contacts the first electrode and the third electrode of the metal-insulator-metal capacitor; and
wherein a slope of a side surface of the first via is different from a slope of a side surface of the second via.

2. The semiconductor device of claim 1, wherein a shape of the first via is different from a shape of the second via.

3. The semiconductor device of claim 1, wherein the first via comprises a trapezoidal shape and the second via comprises at least one of a rectangular shape and a square shape.

4. The semiconductor device of claim 1, further comprising a dielectric layer disposed between the first electrode and the third electrode.

5. The semiconductor device of claim 1, wherein the second via contacts the first electrode and the third electrode at the side surface of the second via.

6. The semiconductor device of claim 1, wherein the second via comprises a first portion contacting the first electrode and the third electrode and a second portion extended from the first portion and contacting the first electrode, and wherein a slope of a side surface of the first portion is different from a slope of a side surface of the second portion.

7. The semiconductor device of claim 6, wherein a dimension of the second portion between side surfaces of the second portion is less than a dimension of the first portion between side surfaces of the first portion.

8. The semiconductor device of claim 6, wherein the first portion and the second portion respectively comprise at least one of a rectangular shape and a square shape.

9. The semiconductor device of claim 1, further comprising a third via extended from the second via and contacting a conductive line of the first metallization level;
wherein a slope of a side surface of the third via is different from the slope of the side surface of the second via.

10. The semiconductor device of claim 9, wherein a shape of the third via is different from a shape of the second via.

11. The semiconductor device of claim 1, further comprising:
a third via extended from and contacting an additional conductive line of the second metallization level;
a fourth via extended from and contacting the third via;
wherein the fourth via contacts the second electrode of the metal-insulator-metal capacitor; and
wherein a slope of a side surface of the third via is different from a slope of a side surface of the fourth via.

12. The semiconductor device of claim 11, wherein a shape of the third via is different from a shape of the fourth via.

13. The semiconductor device of claim 11, wherein the third via comprises a trapezoidal shape and the fourth via comprises at least one of a rectangular shape and a square shape.

14. The semiconductor device of claim 11, wherein the metal-insulator-metal capacitor further comprises a fourth electrode and the fourth via contacts the fourth electrode.

15. A semiconductor device, comprising:
a metal-insulator-metal capacitor; and
at least one interconnect structure disposed between a first metallization level and a second metallization level, wherein:
the at least one interconnect structure comprises a first via and a second via extended from the first via;
the second via contacts one or more electrodes of the metal-insulator-metal capacitor; and
side surfaces of the first via are sloped differently from side surfaces of the second via.

16. The semiconductor device of claim 15, wherein the first via comprises a trapezoidal shape and the second via comprises one of a rectangular shape and a square shape.

17. The semiconductor device of claim 15, wherein the second via contacts a side surface of the one or more electrodes.

18. A semiconductor device, comprising:
a metal-insulator-metal capacitor;
at least two vias connected between a first pair of metal lines respectively corresponding to a first metallization level and a second metallization level, wherein one of the at least two vias contacts a first electrode and a second electrode of the metal-insulator-metal capacitor, and the at least two vias have different shapes from each other; and
at least two other vias connected between a second pair of metal lines respectively corresponding to the first metallization level and the second metallization level, wherein the at least two other vias are isolated from the at least two vias, one of the at least two other vias contacts at least a third electrode of the metal-insulator-metal capacitor, and the at least two other vias have different shapes from each other.

19. The semiconductor device of claim 18, wherein side surfaces of respective ones of the at least two vias are sloped differently from each other.

20. The semiconductor device of claim 18, wherein side surfaces of respective ones of the at least two other vias are sloped differently from each other.
